(19) United States
(12) Patent Application Publication
(10) Pub. No.: US 2006/0214247 A1
(43) Pub. Date: Sep. 28, 2006

(54) Getter deposition for vacuum packaging

(75) Inventors: Jon B. DCamp, Savage, MN (US); Harlan L. Curtis, Champlin, MN (US); Max C. Glenn, Chanhassen, MN (US); Lisa P. Koland, Minneapolis, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/445,059

(22) Filed: Jun. 1, 2006

Related U.S. Application Data
(62) Division of application No. 10/932,906, filed on Sep. 2, 2004.
(60) Provisional application No. 60/570,554, filed on May 13, 2004.

(51) Int. Cl. H01L 29/84

(52) U.S. Cl. 257/416

(57) ABSTRACT

A device package that includes a thin film getter that is deposited on an inside surfaces of a device receiving vacuum sealed cavity or chamber. The thin film getter is deposited using, for example, sputtering, resistive evaporation, e-beam evaporation, or any other suitable deposition technique.

This application is a Divisional application of U.S. patent application Ser. No. 10/932,906, filed on Sep. 2, 2004, which claims priority to U.S. Provisional Application Ser. No. 60/570,554, filed May 13, 2004 and entitled, “Thin Film Getter Deposition For Vacuum Packaging.”

This invention relates to getters, and more particularly, to getters that can be sputtered or otherwise deposited on inside surfaces of a vacuum sealed cavity or chamber.

### BACKGROUND

MEMS devices such as gyroscopes and other devices such as IR detectors often have a need for a good quality and stable vacuum environment to achieve defined performance levels for extended periods of time (e.g. up to 20 years). To help achieve a stable vacuum, a getter is often placed within the vacuum cavity housing the device. Standard industry getters, such as screened or sintered getters, often generate particles in conditions of High G mechanical shock or excessive mechanical vibration. Such particles can be detrimental to the function of the MEMS or other device housed within the vacuum cavity. In addition, many standard industry getters, such as screened or sintered getters, are provided on a plate or other substrate, which is then welded or otherwise secured to the inside of the device package. This can be a time consuming and tedious process, and in some cases, can reduce the reliability and increase the cost of the resulting product. Thus, there is a need for a low-to-no particle generating getter, and/or a getter that can be more easily provided into a desired vacuum cavity.

### SUMMARY

This invention relates to getters, and more particularly, to thin film getters that can be deposited on inside surfaces of a vacuum sealed cavity or chamber. The thin film getter can be deposited using, for example, sputtering, resistive evaporation, e-beam evaporation, or any other suitable deposition technique. There are many applications for such a thin film getter. For example, such a thin film getter can be provided in a vacuum sealed chamber housing a MEMS device, an infrared (1R) detection device such as microbolometer device, as well as many other type of devices that are housed in a reduced pressure or vacuum sealed cavity. It is contemplated that the thin film getter may be deposited directly on, for example, an inner surface of a device package such as a Leadless Chip Carrier (LCC) package or a wire bond package, on an inner surface of a wafer or other substrate facing a vacuum cavity when wafer level packaging is used, or on the inner surface of any other vacuum sealed chamber that houses a device or circuit. In some cases, the thin film getter may be fired (i.e. activated) by the application of heat such as in a vacuum or inert gas prior to, during or after the vacuum seal is created.

### BRIEF DESCRIPTION OF THE DRAWINGS

FIG. 1 is a schematic cross-sectional side view of an illustrative device package with a thin film getter deposited on the back-side of the package lid;

FIG. 2 is a schematic cross-sectional side view of an illustrative device package with a thin film getter deposited on the back-side of the package lid and on the bottom wall of the device receiving cavity;

FIG. 3 is a schematic cross-sectional side view of an illustrative device package with a thin film getter deposited on the side walls of the device receiving cavity;

FIG. 4 is a schematic cross-sectional side view of an illustrative device package with a thin film getter deposited on the back side of the device itself;

FIG. 5 is a top view of an illustrative device package lid with a thin film getter deposited thereon;

FIG. 6 is a schematic cross-sectional side view of an illustrative top wafer and bottom wafer prior to wafer bonding, wherein the top wafer includes a thin film getter deposited thereon;

FIG. 7 is a schematic cross-sectional side view of the illustrative top wafer and bottom wafer of FIG. 6 after wafer bonding;

FIG. 8 is a schematic cross-sectional side view of an illustrative MEMS gyroscope with a lower sense plate on a lower substrate, a device layer and an upper sense plate on an upper substrate prior to bonding the lower substrate, the device layer and the upper substrate, wherein the upper substrate and lower substrate both include a patterned thin film getter; and

FIG. 9 is a schematic cross-sectional side view of the illustrative MEMS gyroscope of FIG. 8 after the lower substrate, the device layer and the upper substrate are bonded together.

### DESCRIPTION

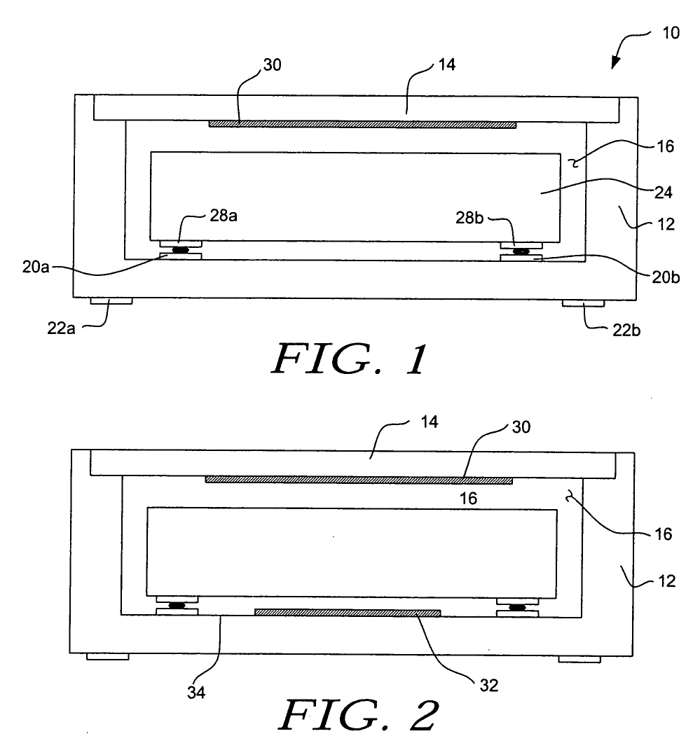

FIG. 1 is a schematic cross-sectional side view of an illustrative device package with a thin film getter. The illustrative package is generally shown at 10, and includes a package housing 12 and a package lid 14 that define a device receiving cavity 16. In the illustrative embodiment, the package is a Leadless Chip Carrier (LCC) package adapted for flip chip die bonding, but it may be any type of package that uses any type of die attach and/or wire bonding, as desired.

In the illustrative embodiment, the package housing 12 includes a number of bond pads 20a and 20b, which may be electrically connected to corresponding surface mount pads 22a and 22b. The surface mount pads 22a and 22b are typically aligned with and adapted to be bonded (e.g. soldered) to corresponding bond pads on a printed circuit board or the like.

The illustrative package housing 12 is configured to be flip-chip bonded to a device 24, however, other types of die bonding, die configurations and/or bonding techniques may be used. The device 24 is only shown schematically, and may be any type of device that might benefit from a reduced pressure or vacuum environment. For example, the device 24 may be a MEMS device such as a gyroscope, an accelerometer, or any other type of MEMS device. In addition, the device 24 may be an IR detection device such as a microbolometer, or any other type of device, as desired.

The illustrative device 24 includes a number of pads 28a and 28b, which are in registration with bond pads 20a and 20b of the package housing 12. The illustrative device 24 is shown flipped over, so that the pads 28a and 28b can be bonded to bond pads 20a and 20b, as is done in conventional flip-chip packaging.

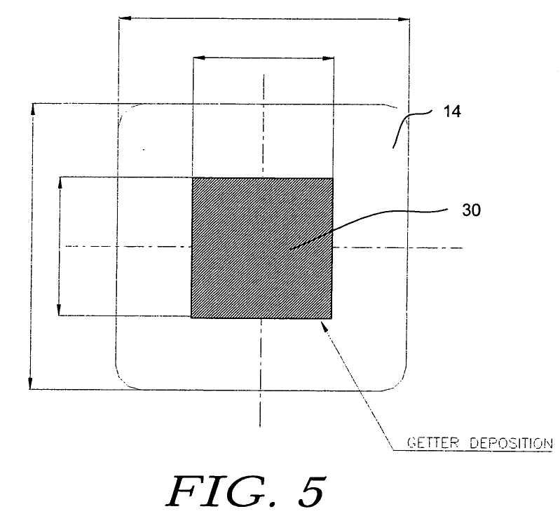

As can be seen, the package housing 12 and package lid 14 define a device receiving cavity 16. During packaging, the device receiving cavity 16 may be exposed to a reduced pressure or vacuum, and the package lid 14 may be secured to the package housing 12, leaving a reduced pressure or vacuum environment in the device receiving cavity 16. In the illustrative embodiment, and to help maintain the reduced pressure or vacuum environment in the device receiving cavity 16 over time, a thin film getter 30 is deposited directly on the back side of the package lid 14. In some embodiments, the thin film getter 30 is also patterned using a suitable patterning process. FIG. 5 is a top view of an illustrative device package lid 14 with a thin film getter deposited and patterned thereon.

The thin film getter 30 may be deposited in any number of ways including, for example, sputtering, evaporation such as resistive or e-beam evaporation, vapor deposition, atomic layer deposition, or any other suitable deposition technique. In some embodiments, the thin film getter 30 may chemically adsorb many or all gases that are anticipated to enter or outgas into the device receiving cavity 16 including, for example, H₂O, O₂, CO, CO₂, N₂, H₂ and/or any other gases, as desired.

The thin film getter 30 may include any desired chemical composition. In some cases, the thin film getter 30 may be Zirconium (Zr) and may be deposited using sputtering techniques. Zr possesses many chemical characteristics which may make it an attractive selection for the thin film getter 30. In other cases, the thin film getter 30 may be Titanium (Ti), Boron (B), Cobalt (Co), Calcium (Ca), Strontium (Sr), Thorium (Th), combinations thereof, or any other suitable getter element, compounds or material. Generally, the thin film getter 30 may be any desired chemical composition deposited by using any desired deposition technique.

In some embodiments, the thin film getter 30 is deposited in a stable form, and does not become active until fired. In some cases, the thin film getter 30 may be fired through the application of heat. With respect to the illustrative embodiment of FIG. 1, the thin film getter 30 may be fired during the package sealing process where elevated temperature may be applied.

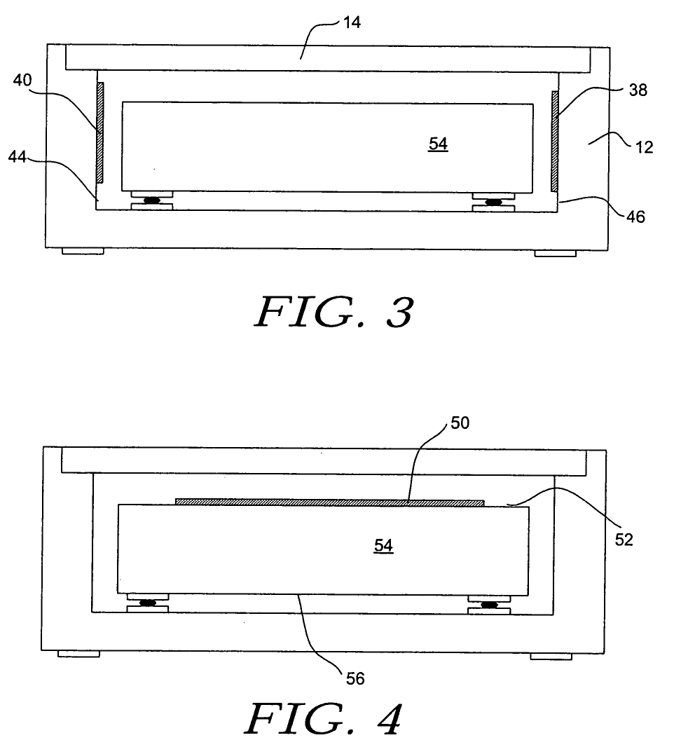

The illustrative embodiment shown in FIG. 2 is similar to that shown in FIG. 1, but further includes a thin film getter 32 deposited directly on the bottom surface 34 of the package housing 12. The illustrative embodiment shown in FIG. 3 is similar to that shown in FIGS. 1 and 2, but includes thin film getters 38 and 40 deposited on the side walls 44 and 46 of the package housing 12. As can be seen, it is contemplated that one or more thin film getters may be deposited anywhere in the device receiving cavity 16, including on the package housing 12 or package lid 14, as desired.

FIG. 4 is a schematic cross-sectional side view of an illustrative device package with a thin film getter 50 deposited on the back side 52 of the device itself 54. In one illustrative embodiment, the device 54 is sawed from a wafer, and has one or more device components (not shown) fabricated on the front side 56 of the device 54. In the illustrative embodiment, the thin film getter 50 is deposited on the back side of the wafer, either prior to or after sawing. The device 54 is then mounted in the package as described above, and in one embodiment, the thin film getter 50 is fired before, during or after the package sealing process. In some embodiments, the thin film getter may be deposited on the front side 56 of the device, such as adjacent to the one or more device components that are fabricated on the front side 56 of the device 54.

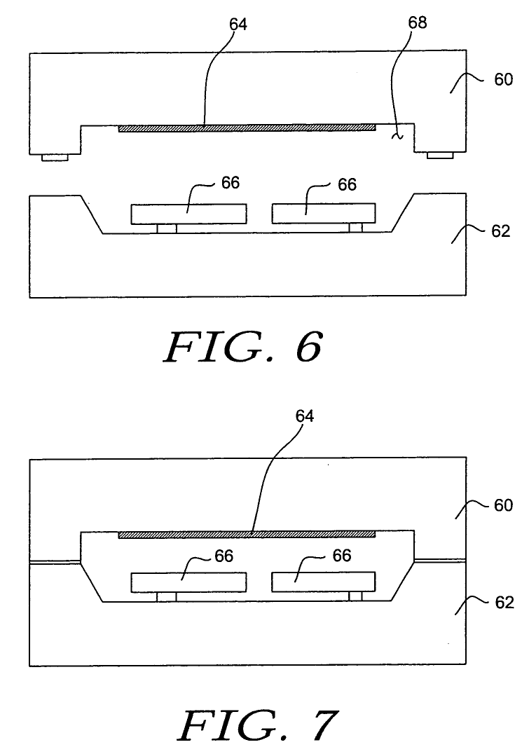

FIG. 6 is a schematic cross-sectional side view of an illustrative top wafer 60 and bottom wafer 62, prior to wafer bonding, wherein the top wafer 60 includes a thin film getter 64 deposited thereon. The illustrative top wafer 60 and bottom wafer 62 may be made from any suitable material or material combination including, for example, silicon, glass, etc. In the illustrative embodiment shown in FIG. 6, the bottom wafer 62 has a number of MEMs components or devices 66 provided thereon. The top wafer 60 includes a recess 68, but this is not required in all embodiments. In the illustrative embodiment, the thin film getter 64 is deposited in the recess 68 of the top wafer. However, it is contemplated that the thin film getter may be deposited anywhere in the cavity that it will be exposed to the vacuum sealed cavity (see FIG. 7).

FIG. 7 is a schematic cross-sectional side view of the illustrative top wafer 60 and bottom wafer 62 of FIG. 6 after wafer bonding. In the illustrative embodiment, the top wafer 60 and bottom wafer 62 are exposed to a reduced pressure or vacuum environment, and then they are bonded together, thereby leaving a reduced pressure or vacuum environment in the cavity that contains the MEMs components or devices 66. Like above, the thin film getter 64 may be fired before, during or after the wafer bonding process.

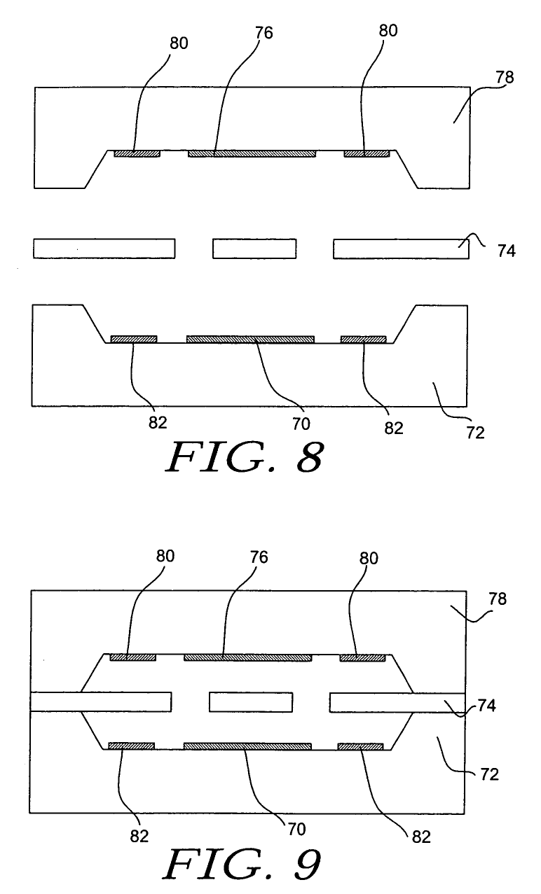

FIG. 8 is a schematic cross-sectional side view of an illustrative MEMS gyroscope with a lower sense plate 70 on a lower substrate 72, a device layer 74 and an upper sense plate 76 on an upper substrate 78 prior to bonding the lower substrate 72, the device layer 74 and the upper substrate 78. In the illustrative embodiment, the upper substrate 78 includes a patterned thin film getter 80, and the lower substrate 72 includes a patterned thin film getter 82. While thin film getters are shown on both the upper substrate 78 and lower substrate 72, it is contemplated that only the upper or lower substrates may include a thin film getter. Also, it is contemplated that a thin film getter may extend over the upper sense plate 76 and/or lower sense plate 70, if desired. Alternatively, or in addition, it is contemplated that a thin film getter may be provided on the device layer 74, such as adjacent to the MEMS mechanism defined therein.

FIG. 9 is a schematic cross-sectional side view of the illustrative MEMS gyroscope of FIG. 8 after the lower substrate 72, the device layer 74 and the upper substrate 78 are bonded together in a vacuum environment. Like above, the thin film getters may be fired before, during or after the wafer bonding process.

Having thus described the several embodiments of the present invention, those of skill in the art will readily appreciate that other embodiments may be made and used which fall within the scope of the claims attached hereto. Numerous advantages of the invention covered by this document have been set forth in the foregoing description. It will be understood that this disclosure is, in many respects, only illustrative. Changes can be made with respect to various elements described herein without exceeding the scope of the invention.

What is claimed is:

1. A device comprising:
a first wafer;
one or more MEMS components fabricated on the first wafer;
a second wafer bonded to the first wafer providing a sealed cavity for the MEMS components; and
a thin film getter deposited on a surface of the second wafer that is exposed to the sealed cavity.

2. The device of claim 1, wherein the second wafer includes a recess, and wherein the thin film getter is deposited in the recess of the second wafer.

3. The device of claim 1, wherein the thin film getter is activated before the second wafer is bonded to the first wafer.

4. The device of claim 1, wherein the thin film getter is activated after the second wafer is bonded to the first wafer.

5. The device of claim 1, wherein the thin film getter is deposited on the surface of the second wafer by sputtering.

6. The device of claim 1, wherein the thin film getter is deposited on the surface of the second wafer by evaporation.

7. The device of claim 1, wherein the thin film getter is deposited on the surface of the second wafer by vapor deposition.

8. The device of claim 1, wherein the thin film getter is deposited on the surface of the second wafer by atomic layer deposition.

9. The device of claim 1, wherein the thin film getter includes Zirconium.

10. The device of claim 1, wherein the thin film getter includes Titanium.

11. The device of claim 1, wherein the thin film getter includes Boron.

12. A MEMS gyroscope comprising:
a first substrate;
a second substrate bonded to the first substrate forming a sealed cavity formed between the first substrate and the second substrate;
a first sense plate provided on the first substrate within the sealed cavity;
a second sense plate provided on the second substrate within the sealed cavity;
a device layer provided within the sealed cavity formed between the first substrate and the second substrate, the device layer having one or more MEMS components fabricated thereon; and
a patterned thin film getter provided on a surface of the first substrate and on a surface of the second substrate so that the patterned thin film getter is exposed to the sealed cavity.

13. The MEMS gyroscope of claim 12, wherein the patterned thin film getter is also provided on a surface of the first sense plate and on a surface of the second sense plate.

14. The MEMS gyroscope of claim 12, wherein the patterned thin film getter is activated before the second substrate is bonded to the first substrate.

15. The MEMS gyroscope of claim 12, wherein the patterned thin film getter is activated after the second substrate is bonded to the first substrate.

16. The MEMS gyroscope of claim 12, wherein the patterned thin film getter is provided on the surface of the first substrate and on the surface of the second substrate by sputtering.

17. The MEMS gyroscope of claim 12, wherein the patterned thin film getter is provided on the surface of the first substrate and on the surface of the second substrate by evaporation.

18. The MEMS gyroscope of claim 12, wherein the patterned thin film getter is provided on the surface of the first substrate and on the surface of the second substrate by vapor deposition.

19. The MEMS gyroscope of claim 12, wherein the patterned thin film getter is provided on the surface of the first substrate and on the surface of the second substrate by atomic layer deposition.

20. The MEMS gyroscope of claim 12, wherein the patterned thin film getter includes material selected from the group consisting of Zirconium, Titanium and Boron.
